(19) United States
(12) Patent Application Publication
(10) Pub. No.: US 2026/0082745 A1
(43) Pub. Date: Mar. 19, 2026

(54) METHOD FOR MANUFACTURING LIGHT-EMITTING DEVICE, LIGHT-EMITTING DEVICE, AND LIGHT-EMITTING MODULE

(71) Applicant: NICHIA CORPORATION, Anan-shi (JP)

(72) Inventors: Yasunobu HOSOKAWA, Tokushima-shi (JP); Naoya SAKO, Anan-shi (JP)

(73) Assignee: NICHIA CORPORATION, Anan-shi (JP)

(21) Appl. No.: 19/327,908

(22) Filed: Sep. 12, 2025

(30) Foreign Application Priority Data
Sep. 17, 2024 (JP) 2024-160298

(51) Int. Cl. H10H 29/01; H10H 29/03; H10H 29/85; H10H 29/851

(52) U.S. Cl. CPC H10H 29/0361; H10H 29/03; H10H 29/8514; H10H 29/857

(57) ABSTRACT

A method for manufacturing a light-emitting device includes: providing a structure including: a plurality of light-emitting elements each having a light-emitting surface, and a support member disposed at least between the plurality of light-emitting elements and supporting the plurality of light-emitting elements; disposing, on the structure, a mask member covering the support member between the plurality of light-emitting elements, the mask member defining a plurality of openings each positioned above a corresponding one of the light-emitting surfaces of the plurality of light-emitting elements; disposing a plurality of wavelength conversion members in the plurality of openings; and after disposing the plurality of wavelength conversion members, removing the mask member and the support member between the plurality of light-emitting elements.

### CROSS-REFERENCE TO RELATED APPLICATION

This application claims priority to Japanese Patent Application No. 2024-160298, filed on Sep. 17, 2024, the disclosure of which is hereby incorporated by reference in its entirety.

### TECHNICAL FIELD

The present disclosure relates to a method for manufacturing a light-emitting device, a light-emitting device, and a light-emitting module.

### BACKGROUND

For example, International Publication No. WO 2019/092893 discloses a method for manufacturing a light-emitting module including the steps of peeling off a growth substrate from a plurality of light-emitting elements after transferring the plurality of light-emitting elements on the growth substrate to a base substrate, forming a light shielding layer on the base substrate so as to cover the plurality of light-emitting elements, removing the light shielding layer on upper surfaces of the light-emitting elements, and forming a color conversion layer on the upper surfaces of the light-emitting elements.

### SUMMARY

An object of the present disclosure is to provide a method for manufacturing a light-emitting device, a light-emitting device, and a light-emitting module, in which, when light emission control is individually performed for a plurality of light-emitting elements, light emitted from a light-emitting element that is intentionally lit is less likely to enter into a wavelength conversion member located on a light-emitting element that is intentionally unlit can be reduced.

According to an aspect of the present disclosure, there is provided a method for manufacturing a light-emitting device, the method including: providing a structure including a plurality of light-emitting elements and a support member, each of the plurality of light-emitting elements having a light-emitting surface, and the support member being disposed at least between the plurality of light-emitting elements and supporting the plurality of light-emitting elements; disposing, on the structure, a mask member covering the support member between the plurality of light-emitting elements, the mask member having a plurality of openings disposed above each of the light-emitting surfaces of the plurality of light-emitting elements, one of the openings being disposed above one of the light-emitting surfaces, disposing wavelength conversion members in the plurality of openings; and after disposing the wavelength conversion members, removing the mask member and the support member between the plurality of light-emitting elements.

According to an aspect of the present disclosure, there is provided a light-emitting device including: a light-emitting element including a light-emitting surface, the light-emitting surface including an outer peripheral region and an inner region surrounded by the outer peripheral region in a plan view, the inner region having a greater surface roughness than the outer peripheral region; and a wavelength conversion member disposed on the light-emitting surface, in which a lower surface of the wavelength conversion member is positioned on the inner region and is not positioned on the outer peripheral region.

According to an aspect of the present disclosure, a light-emitting device module includes: a wiring substrate; a plurality of the light-emitting devices, each of the plurality of the light-emitting devices being disposed on the wiring substrate, with a surface positioned on the opposite side of the light-emitting surface of the light-emitting elements to face the wiring substrate; and a light-reflective member disposed between each of the light-emitting elements of the plurality of light-emitting devices and between each of the wavelength conversion members of the plurality of the light-emitting devices.

According to the present disclosure, provided are a method for manufacturing a light-emitting device, a light-emitting device, and a light-emitting module, in which, when light emission control is individually performed for the plurality of light-emitting elements, light emitted from a light-emitting element that is intentionally lit is less likely to enter into a wavelength conversion member located on a light-emitting element that is intentionally unlit can be reduced.

### BRIEF DESCRIPTION OF DRAWINGS

FIG. 1 is a schematic plan view of a light-emitting device according to a first embodiment.

FIG. 2 is a schematic cross-sectional view taken along line II-II in FIG. 1.

FIG. 3 is a schematic plan view of a light-emitting device according to a second embodiment.

FIG. 4 is a schematic cross-sectional view taken along line IV-IV in FIG. 3.

FIG. 5 is a schematic cross-sectional view of a light-emitting module according to an embodiment.

FIG. 6 is a schematic cross-sectional view for illustrating a step of a method for manufacturing the light-emitting element according to the first embodiment.

FIG. 7 is a schematic cross-sectional view for illustrating a step of the method for manufacturing the light-emitting element according to the first embodiment.

FIG. 8 is a schematic cross-sectional view for illustrating a step of the method for manufacturing the light-emitting element according to the first embodiment.

FIG. 9 is a schematic cross-sectional view for illustrating a step of the method for manufacturing the light-emitting element according to the first embodiment.

FIG. 10 is a schematic cross-sectional view for illustrating a step of the method for manufacturing the light-emitting element according to the first embodiment.

FIG. 11 is a schematic cross-sectional view for illustrating a step of the method for manufacturing the light-emitting element according to the first embodiment.

FIG. 12 is a schematic cross-sectional view for illustrating a step of the method for manufacturing the light-emitting element according to the first embodiment.

FIG. 13 is a schematic plan view for illustrating a step of the method for manufacturing the light-emitting element according to the first embodiment.

FIG. 14 is a schematic cross-sectional view taken along line XIV-XIV in FIG. 13.

FIG. 15 is a schematic plan view for illustrating a step of the method for manufacturing the light-emitting element according to the first embodiment.

FIG. 16 is a schematic cross-sectional view taken along line XVI-XVI of FIG. 15.

FIG. 17 is a schematic cross-sectional view for illustrating a step of the method for manufacturing the light-emitting element according to the first embodiment.

FIG. 18 is a schematic cross-sectional view for illustrating a step of the method for manufacturing the light-emitting element according to the first embodiment.

FIG. 19 is a schematic cross-sectional view for illustrating a step of the method for manufacturing the light-emitting element according to the first embodiment.

FIG. 20 is a schematic plan view for illustrating a step of a method for manufacturing a light-emitting element according to the second embodiment.

FIG. 21 is a schematic cross-sectional view taken along line XXI-XXI in FIG. 20.

FIG. 22 is a schematic cross-sectional view for illustrating a step of the method for manufacturing the light-emitting element according to the second embodiment.

### DETAILED DESCRIPTION

Embodiments are described below with reference to the drawings. Dimensions, materials, shapes, relative arrangements, or the like of constituent members described in the embodiments are not intended to be limited to the scope of the present disclosure, unless otherwise specified, and are merely exemplary. Note that the sizes, positional relationship, or the like of members illustrated in each of the drawings may be exaggerated for clarity of description. Furthermore, in the following description, members having the same names and reference signs represent the same or similar members, and detailed description of these members is omitted as appropriate. As a cross-sectional view, an end view illustrating only a cut surface may be illustrated.

In the following description, terms indicating specific directions or positions (for example, “upper,” “above,” “lower,” “below” and other terms related to those terms) may be used. However, these terms are used merely to make it easy to understand relative directions or positions in the referenced drawing. As long as the relative direction or position is the same as that described in the referenced drawing using the term such as “upper,” “above,” “lower,” or “below” in drawings other than the drawings of the present disclosure, actual products, and the like, components need not be arranged in the same manner as that in the referenced drawing. For example, on the assumption that there are two members, the positional relationship expressed as “upper (or lower)” in the present specification may include a case in which the two members are in contact with each other and a case in which the two members are not in contact with each other and one of the two members is located above (or below) the other member. The term “on” in the present disclosure encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and in contact with another member and a configuration in which a member covers another member with a space or an intervening member interposed therebetween.

In the following drawings, directions may be indicated by an X-axis, a Y-axis, and a Z-axis. The X-axis, the Y-axis, and the Z-axis are orthogonal to each other. For example, in the present specification, the direction of the Z-axis is referred to as a first direction Z, the direction of the X-axis is referred to as a second direction X, and the direction of the Y-axis is referred to as a third direction Y. In addition, in the present specification, an arrow direction of the Z-axis is a main extraction direction of light.

### Light-Emitting Device According to First Embodiment

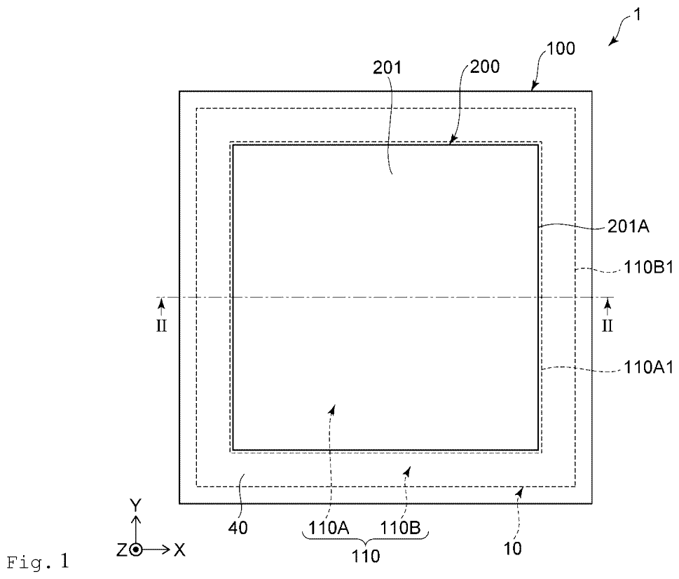

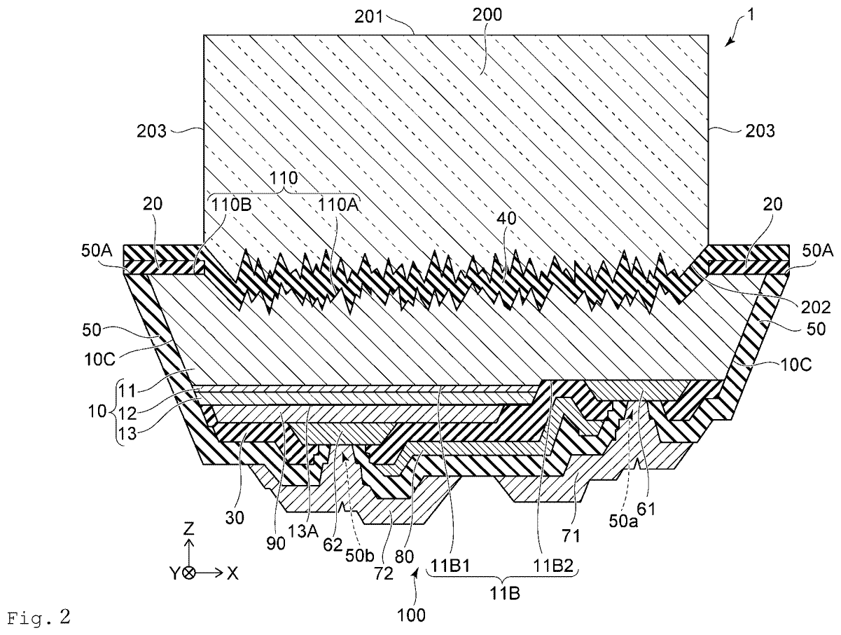

A light-emitting device 1 according to a first embodiment will be described with reference to FIGS. 1 and 2. The light-emitting device 1 includes a light-emitting element 100 and a wavelength conversion member 200.

As illustrated in FIG. 1, in a plan view, the shape of the light-emitting element 100 and the shape of the wavelength conversion member 200 are, for example, rectangular. In a plan view, the outer edge of the wavelength conversion member 200 is positioned inward of the outer edge of the light-emitting element 100. A length of one side of the light-emitting element 100 in a plan view is, for example, in a range from 10 μm to 200 μm.

### Light-Emitting Element

The light-emitting element 100 includes a light-emitting surface 110. The light-emitting surface 110 is a surface through which light is mainly extracted from the light-emitting element 100. The light-emitting surface 110 has an outer peripheral region 110B and an inner region 110A surrounded by the outer peripheral region 110B in a plan view. In a plan view, the outer edge 110A1 of the inner region 110A is positioned inward of the outer edge 110B1 of the outer peripheral region 110B. In a plan view, an area of the inner region 110A is greater than an area of the outer peripheral region 110B. The outer peripheral region 110B is, for example, a region of the light-emitting surface 110 within a range of 10 μm or less, preferably within a range of 5 μm or less from the outer edge of the light-emitting surface 110 in a plan view.

A surface roughness of the inner region 110A is greater than that of the outer peripheral region 110B. Accordingly, light is more easily extracted from the inner region 110A than from the outer peripheral region 110B. In the present specification, the surface roughness is, for example, an average surface roughness Ra. The average surface roughness Ra of the inner region 110A is in a range from 100 nm to 400 nm, for example. The average surface roughness Ra of the outer peripheral region 110B is in a range from 1 nm to 10 nm, for example. The surface roughness of the inner region 110A and the surface roughness of the outer peripheral region 110B may be measured by, for example, a laser microscope or an atomic force microscope. Because the light-emitting surface 110 includes the outer peripheral region 110B, the occurrence of chipping in a semiconductor structure 10 may be reduced as will be described later.

### Wavelength Conversion Member

The wavelength conversion member 200 is disposed on the light-emitting surface 110 of the light-emitting element 100. The wavelength conversion member 200 includes, for example, a base material formed of a light-transmissive material and a phosphor dispersed in the base material. As materials of the base material, for example, an epoxy resin, a silicone resin, a resin obtained by mixing the epoxy resin and the silicone resin, glass, or the like may be used. A part of the light extracted from the light-emitting surface 110 of the light-emitting element 100 enters the wavelength conversion member 200 and is converted into wavelength by the phosphor. For example, the color of the wavelength-converted light is yellow. As the yellow phosphor, for example, a phosphor having a composition represented by Y₃Al₅O₁₂:Ce or (Y,Lu,Gd)₃(Al,Ga)₅O₁₂:Ce may be used. In a case in which the yellow phosphor having such a composition is used, a light emission peak wavelength of the light emitted from an active layer 12 of the light-emitting element 100, which will be described later, is preferably in a range from 420 nm to 490 nm, for example. A thickness of the wavelength conversion member 200 is, for example, in a range from 5 μm to 50 μm.

The wavelength conversion member 200 includes an upper surface 201, a lower surface 202 positioned on the opposite side of the upper surface 201 in the first direction Z, and a lateral surface 203 connecting the upper surface 201 and the lower surface 202. In the light-emitting device 1, light is mainly extracted from the upper surface 201 and the lateral surface 203 of the wavelength conversion member 200. In the example illustrated in FIG. 2, an angle formed by the upper surface 201 and the lateral surface 203 is substantially a right angle. The lower surface 202 of the wavelength conversion member 200 is positioned on the inner region 110A of the light-emitting surface 110 and is not positioned on the outer peripheral region 110B.

For example, in a case in which the lower surface 202 of the wavelength conversion member 200 is positioned on the outer peripheral region 110B, light emitted from the light-emitting elements 100 is less likely to enter the wavelength conversion member 200 from the outer peripheral region 110B than light from the inner region 110A. This is because the surface roughness of the outer peripheral region 110B is smaller than the surface roughness of the inner region 110A. Therefore, in a case in which the lower surface 202 of the wavelength conversion member 200 is positioned on the outer peripheral region 110B, the chromaticity is likely to vary on the upper surface 201 of the wavelength conversion member 200. According to the present embodiment, because the lower surface 202 of the wavelength conversion member 200 is not positioned on the outer peripheral region 110B, chromaticity variation on the upper surface 201 of the wavelength conversion member 200 may be reduced.

According to the present embodiment, the light-emitting element 100 can have a configuration described below.

### Semiconductor Structure

As illustrated in FIG. 2, the light-emitting element 100 includes the semiconductor structure 10. The semiconductor structure 10 is formed of a nitride semiconductor. In the present specification, for example, it is assumed that the “nitride semiconductor” includes semiconductors having all compositions in which the composition ratios x and y are changed within the respective ranges in a chemical formula of InₓAl_{y}Ga_{1-x-y}N (0≤x≤1, 0≤y≤1, x+y≤1). It is assumed that the “nitride semiconductor” includes, in its category, a semiconductor further containing a group V element other than nitrogen (N) in the above chemical formula, and a semiconductor further containing, in the above chemical formula, any of various elements added to control any of various physical properties such as a conductivity type.

The semiconductor structure 10 includes a first semiconductor layer 11, the active layer 12, and a second semiconductor layer 13. The active layer 12 is positioned between the first semiconductor layer 11 and the second semiconductor layer 13 in the first direction Z. The first semiconductor layer 11 includes a semiconductor layer containing n-type impurities. The second semiconductor layer 13 includes a semiconductor layer containing p-type impurities. The active layer 12 is a light-emitting layer that emits light and has a multiple quantum well (MQW) structure including a plurality of barrier layers and a plurality of well layers, for example. The active layer 12 emits light having a light emission peak wavelength in a range from 210 nm to 580 nm, for example.

The first semiconductor layer 11 has a first surface and a second surface 11B positioned on a side opposite the first surface in the first direction Z. The first surface of the first semiconductor layer 11 constitutes a light-emitting surface 110 of the light-emitting element 100.

The second surface 11B of the first semiconductor layer 11 includes a first region 11B1 and a second region 11B2. In a plan view, an area of the first region 11B1 is greater than an area of the second region 11B2. The active layer 12 and the second semiconductor layer 13 are disposed in the first region 11B1. The active layer 12 is positioned between the first region 11B1 and the second semiconductor layer 13.

In the vicinity of the outer edge of the semiconductor structure 10, the semiconductor structure 10 tends to chip. According to the embodiment, by the surface roughness of the outer peripheral region 110B of the light-emitting surface 110 being smaller than the surface roughness of the inner region 110A, strength in the vicinity of the outer edge of the light-emitting surface 110 can be increased, in comparison with a case in which the surface roughness of the outer peripheral region 110B is equal to the surface roughness of the inner region 110A, and a case in which the surface roughness of the outer peripheral region 110B is greater than the surface roughness of the inner region 110A, so that occurrence of chipping in the semiconductor structure 10 can be reduced.

### First Protective Film

The light-emitting element 100 includes a first protective film 20. The first protective film 20 is disposed in the outer peripheral region 110B of the light-emitting surface 110. As materials for the first protective film 20, for example, SiO₂, SiON, or SiN may be used. A thickness of the first protective film 20 is, for example, in a range from 0.2 μm to 2 μm. Here, the thickness of the first protective film 20 refers to a maximum thickness of the first protective film 20 in the first direction Z.

### Second Protective Film

A second protective film 40 is continuously disposed on the inner region 110A of the light-emitting surface 110 and on the first protective film 20. As materials of the second protective film 40, for example, SiO₂, SiON, or SiN may be used. A thickness of the second protective film 40 is, for example, in a range from 0.1 μm to 1 μm. The second protective film 40 is positioned between the inner region 110A of the light-emitting surface 110 and the lower surface 202 of the wavelength conversion member 200. The second protective film 40 covers the roughened inner region 110A, so that an upper surface of the second protective film 40 also becomes a rough surface. The surface roughness of the second protective film 40 on the inner region 110A is greater than the surface roughness of the second protective film 40 disposed on the outer peripheral region 110B via the first protective film 20.

The lower surface 202 of the wavelength conversion member 200 covers the upper surface of the second protective film 40 along the upper surface of the second protective film 40. Therefore, the lower surface 202 of the wavelength conversion member 200 becomes rough. Accordingly, the incidence efficiency of light from the second protective film 40 to the wavelength conversion member 200 can be improved.

### First Electrode and Second Electrode

The light-emitting element 100 includes a first electrode 61 and a second electrode 62. The first electrode 61 is disposed on the second region 11B2 of the second surface 11B of the first semiconductor layer 11, and is electrically connected to the first semiconductor layer 11. The second electrode 62 is disposed on a surface 13A side of the second semiconductor layer 13, the surface 13A being positioned on an opposite side of the active layer 12, and is electrically connected to the second semiconductor layer 13. The first electrode 61 and the second electrode 62 may be a single-layer metal layer containing, for example, Ti, Rh, Au, Pt, Al, Ag, or Ru, or a multilayer structure containing at least two of these metal layers.

### Light-Transmissive Conductive Film

The light-emitting element 100 includes a light-transmissive conductive film 90. The light-transmissive conductive film 90 is disposed in contact with the surface 13A of the second semiconductor layer 13 on the side opposite the active layer 12. The second electrode 62 is disposed in contact with the light-transmissive conductive film 90. The second electrode 62 is electrically connected to the second semiconductor layer 13 via the light-transmissive conductive film 90. The light-transmissive conductive film 90 can diffuse a current supplied via the second electrode 62, in a planar direction of the second semiconductor layer 13. As materials of the light-transmissive conductive film 90, for example, indium tin oxide (ITO), indium zinc oxide (IZO), Zno, or In₂O₃ may be used.

### First Reflective Film

The light-emitting element 100 includes a first reflective film 30. The first reflective film 30 covers at least the surface 13A side of the second semiconductor layer 13, the surface 13A being positioned on an opposite side of the active layer 12. The first reflective film 30 has light reflectivity with respect to light emitted from the active layer 12. Reflectance of the first reflective film 30 with respect to a light emission peak wavelength of light emitted from the active layer 12 is, for example, 40% or more, preferably 60% or more. Light that has traveled from the active layer 12 toward the second semiconductor layer 13 on a side opposite the light-emitting surface 110 may be reflected by the first reflective film 30 toward the inner region 110A of the light-emitting surface 110.

Accordingly, light extraction efficiency from the inner region 110A can be improved.

The first reflective film 30 can cover substantially the entire surface of the semiconductor structure 10 on a side opposite the light-emitting surface 110. As a result, the amount of light reflected to the inner region 110A is increased, and the light extraction efficiency from the inner region 110A can be further improved.

The first reflective film 30 may include, for example, a dielectric multilayer film. The dielectric multilayer film may include a plurality of first films and a plurality of second films. The first film and the second film are alternately stacked in the first direction Z. For example, the first film contains Nb₂O₅, and the second film contains SiO₂.

### Second Reflective Film

The light-emitting element 100 includes a second reflective film 80 stacked on the first reflective film 30. The second reflective film 80 reflects the light transmitted through the first reflective film 30 toward the inner region 110A, so that the light extraction efficiency can be improved. The second reflective film 80 is, for example, a metal film. The second reflective film 80 includes, for example, Al, Ti, or a multilayer structure thereof.

### Insulating Film

The light-emitting element 100 includes an insulating film 50. The insulating film 50 is disposed on a lateral surface 10C of the semiconductor structure 10 to protect the lateral surface 10C. As a material of the insulating film 50, for example, SiO₂ may be used. The first protective film 20 covers the upper surface 50A of the insulating film 50 disposed on the lateral surface 10C of the semiconductor structure 10.

The insulating film 50 may be disposed on the surface side of the semiconductor structure 10 positioned on a side opposite the light-emitting surface 110 so as to cover the first reflective film 30, the second reflective film 80, the first electrode 61, and the second electrode 62.

### First Conductive Member and Second Conductive Member

The light-emitting element 100 includes a first conductive member 71 and a second conductive member 72. The first conductive member 71 and the second conductive member 72 are disposed on the insulating film 50 so as to be spaced apart from each other. The first conductive members 71 may be connected to the first electrodes 61 in a first opening 50a formed in the insulating film 50. The second conductive members 72 may be connected to the second electrodes 62 in a second opening 50b formed in the insulating film 50. The first conductive member 71 and the second conductive member 72 include, for example, Ti, Rh, Au, Pt, Ru, Al, or a multilayer structure of any two of these.

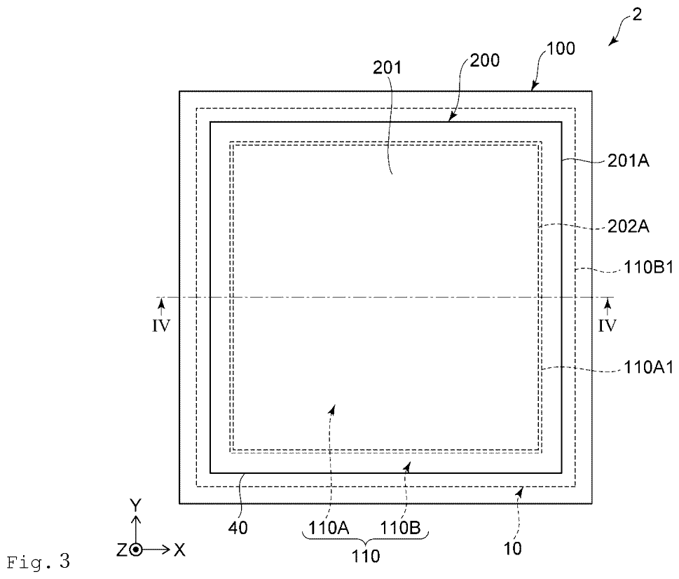

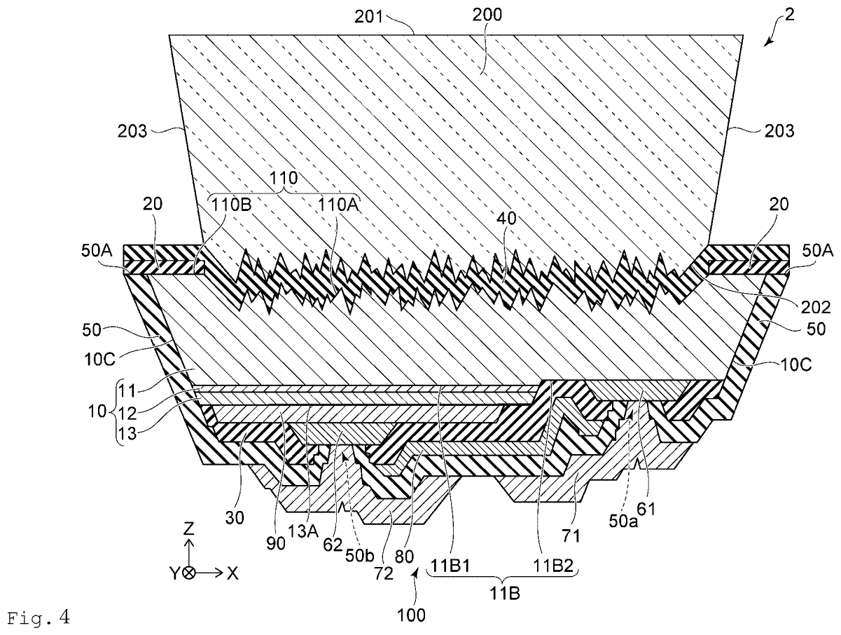

Light-Emitting Device According to Second Embodiment A light-emitting device 2 according to a second embodiment will be described with reference to FIGS. 3 and 4.

The light-emitting device 2 according to the second embodiment differs from the light-emitting device 1 according to the first embodiment in that the shape of a wavelength conversion member 200 is different.

Also in the present embodiment, a lower surface 202 of the wavelength conversion member 200 is positioned on an inner region 110A of a light-emitting surface 110 and is not positioned on an outer peripheral region 110B. In addition, according to the present embodiment, as illustrated in FIG. 3, in a plan view, an outer edge 201A of an upper surface 201 of the wavelength conversion member 200 is positioned outward of an outer edge 202A of the lower surface 202 and overlaps the outer peripheral region 110B of the light-emitting surface 110. As illustrated in FIG. 4, the angle formed by the upper surface 201 and a lateral surface 203 of the wavelength conversion member 200 is an acute angle. Toward the upper surface 201 from the lower surface 202, each of a width in the second direction X and a width in the third direction Y of the wavelength conversion member 200 becomes larger. According to the present embodiment, an area of the upper surface 201 can be made larger than that in the first embodiment while the lower surface 202 of the wavelength conversion member 200 is not positioned on the outer peripheral region 110B of the light-emitting surface 110. Accordingly, a light-emitting area of the light-emitting device 2 can be increased while reducing variations in chromaticity.

### Light-Emitting Module

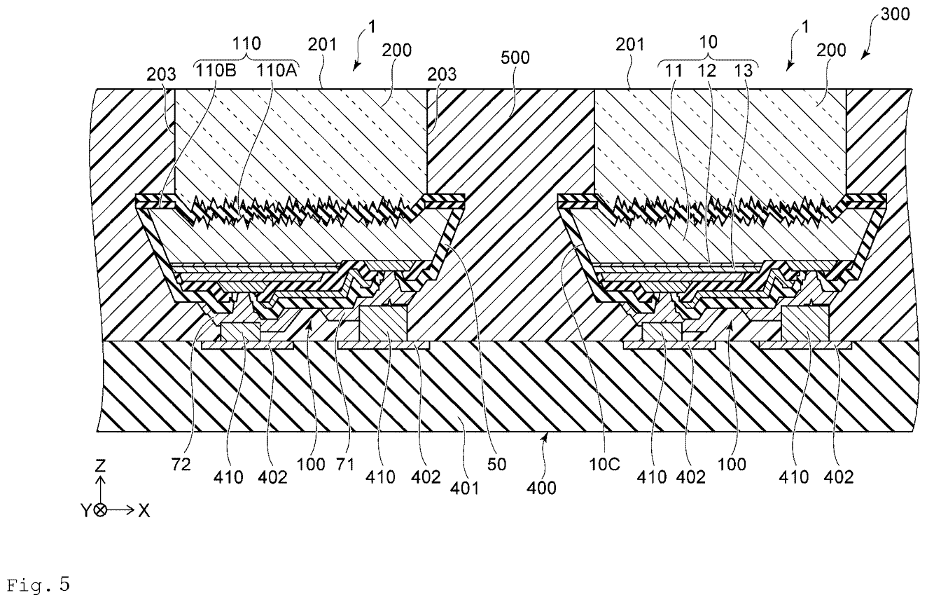

A light-emitting module 300 according to an embodiment is described with reference to FIG. 5.

The light-emitting module 300 according to the embodiment includes a wiring substrate 400 and the above-described light-emitting device 1 disposed on the wiring substrate 400. For example, the plurality of light-emitting devices 1 are disposed on an upper surface of the wiring substrate 400. Each of the light-emitting devices 1 is disposed on an upper surface of a wiring substrate 400 with a surface positioned on a side opposite the light-emitting surface 110 of the light-emitting element 100 facing the upper surface of the wiring substrate 400. Note that, a light-emitting device included in the light-emitting module 300 may be the light-emitting device 2 according to the second embodiment.

The wiring substrate 400 includes an insulating base body 401 and a wiring portion 402 disposed at least on an upper surface of the insulating base body 401. The first conductive member 71 and the second conductive member 72 of the light-emitting device 1 are bonded to the wiring portion 402 via a conductive connection member 410 and are electrically connected to the wiring portion 402. As materials of the connection member 410, for example, Cu, Au, or the like may be used. A current is supplied to the light-emitting device 1 via the wiring portion 402 and the connection member 410. Each of a plurality of light-emitting devices 1 can perform individual lighting control.

The light-emitting module 300 further includes a light-reflective member 500. On the wiring substrate 400, the light-reflective member 500 is disposed between each of the light-emitting elements 100 of the plurality of light-emitting devices 1, and between each of the wavelength conversion members 200 of the plurality of light-emitting devices 1. The light-reflective member 500 is in contact with the lateral surface 203 of the wavelength conversion member 200. The upper surface 201 of the wavelength conversion member 200 is exposed from the light-reflective member 500. The light-reflective member 500 covers the lateral surface 10C of the semiconductor structure 10 via the insulating film 50. For example, the light-reflective member 500 is disposed between the lower surface of the light-emitting element 100 and the upper surface of the wiring substrate 400.

The light-reflective member 500 has reflectivity to light emitted from the light-emitting device 1. Reflectance of the light-reflective member 500 with respect to a light emission peak wavelength of light converted by the wavelength conversion member 200 from light emitted from the active layer 12 is, for example, 60% or more, and preferably 80% or more. The light-reflective member 500 includes, for example, a base material and a light diffusing agent for diffusely reflecting light emitted from the light-emitting device 1. As materials for the base material of the light-reflective member 500, for example, a silicone resin, an epoxy resin, an acrylic resin, or the like may be used. As the light diffusing agent of the light-reflective member 500, for example, TiO₂, SiO₂, Al₂O₃, Zno, MgO, ZrO₂, Y₂O₃, CaF₂, MgF₂, Nb₂O₅, BaTiO₃, Ta₂O₅, BaSO₄, or particles of glass or the like may be used.

Here, as a comparative example, a light-emitting module is considered in which a wavelength conversion member is continuously disposed on the upper surface of each light-emitting element 100 and on a region between adjacent light-emitting elements 100 so as to extend over a plurality of light-emitting elements 100. In a case in which light emission control is individually performed for the plurality of light-emitting elements 100 of the light-emitting module of this comparative example, light emitted from the light-emitting element 100 that is intentionally lit likely to enter into the wavelength conversion member on the adjacent light-emitting elements 100 that are intentionally unlit, and a phosphor contained in the wavelength conversion member on the light-emitting element 100 that is intentionally unlit is likely to be caused to emit light.

According to the present embodiment, the plurality of wavelength conversion members 200 are separately disposed for each of the plurality of light-emitting elements 100, and the light-reflective member 500 is disposed between the adjacent light-emitting elements 100 and between the adjacent wavelength conversion members 200. Accordingly, when light emission control is individually performed for the plurality of light-emitting elements 100, light emitted from the light-emitting element 100 that is intentionally lit is less likely to enter into the wavelength conversion member 200 on the light-emitting element 100 that is intentionally unlit. When the light-emitting module 300 is observed from the upper surface 201 side of the wavelength conversion member 200, the light-emitting module 300 can have a large difference in luminance between the upper surface 201 of the wavelength conversion member 200 on the light-emitting element 100 that is intentionally lit and the upper surface 201 of the wavelength conversion member 200 on the light-emitting element 100 that is intentionally unlit.

### Method for Manufacturing Light-Emitting Device According to First Embodiment

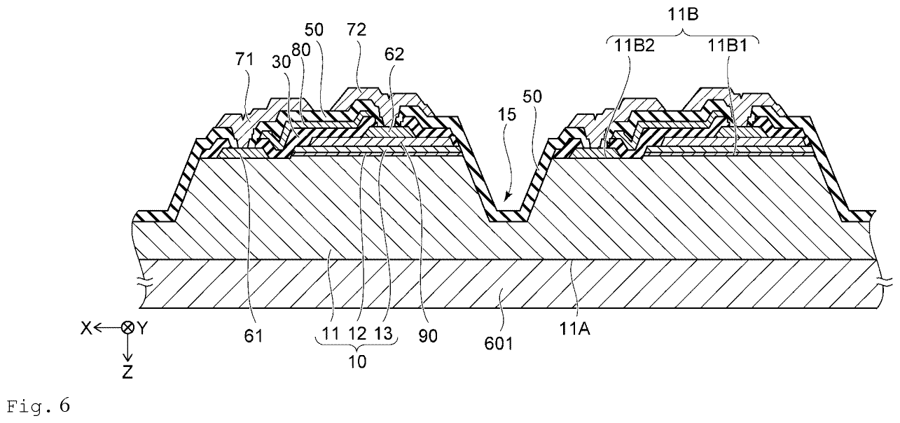

A method for manufacturing the light-emitting device according to the first embodiment is described with reference to FIGS. 6 to 19.

### Step of Providing Structure

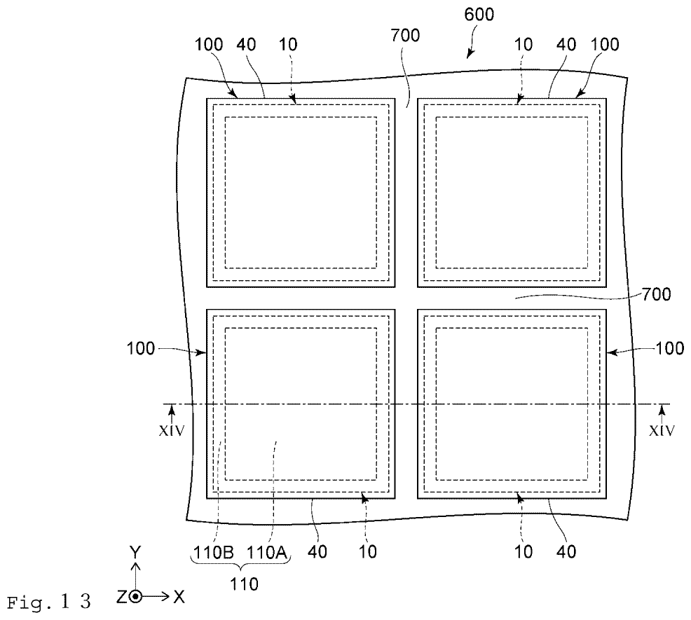

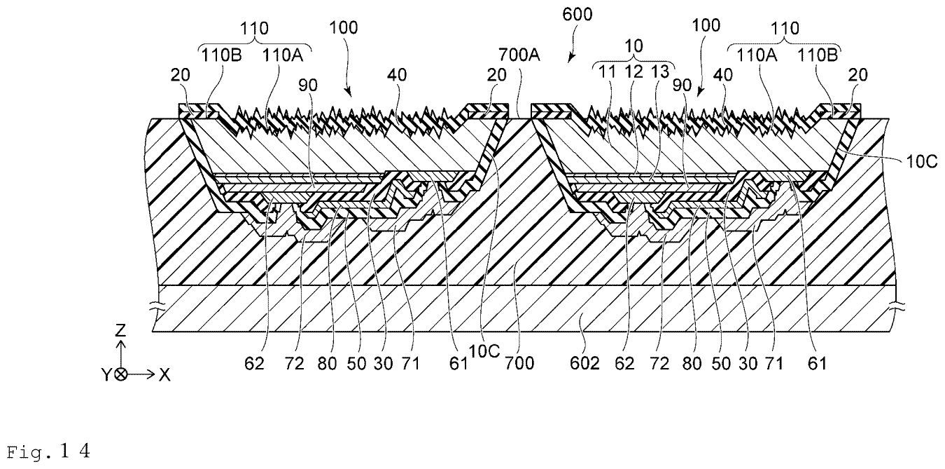

The method for manufacturing the light-emitting device according to the first embodiment includes a step of providing a structure 600 illustrated in FIGS. 13 and 14. The structure 600 includes the plurality of light-emitting elements 100 and a support member 700.

As illustrated in FIG. 14, each of the light-emitting elements 100 includes, as described above, the semiconductor structure body 10, the first protective film 20, the second protective film 40, the light-transmissive conductive film 90, the first electrode 61, the second electrode 62, the first reflective film 30, the second reflective film 80, the insulating film 50, the first conductive member 71, and the second conductive member 72.

The support member 700 is disposed at least between the plurality of light-emitting elements 100 and supports the plurality of light-emitting elements 100. As illustrated in FIG. 13, the plurality of light-emitting elements 100 are arranged side by side in the second direction X and the third direction Y. The support member 700 is disposed between the light-emitting elements 100 adjacent to each other in the second direction X, and between the light-emitting elements 100 adjacent to each other in the third direction Y.

In addition, the support member 700 is disposed on a surface (lower surface in the light-emitting element 100 illustrated in FIG. 14) side positioned on the opposite side of the light-emitting surface 110 in the light-emitting element 100. The support member 700 disposed between the adjacent light-emitting elements 100 covers the lateral surface 10C of the semiconductor structure 10 via the insulating film 50. The support member 700 covers the insulating film 50, the first conductive member 71, and the second conductive member 72 on the surface side of the light-emitting element 100 opposite the light-emitting surface 110. In the structure 600, the second protective film 40 is exposed from the support member 700. The support member 700 is a resin member including, for example, an epoxy resin, an acrylic resin, a polyimide resin, or the like.

The step of providing a structure 600 can have the steps described below with reference to FIGS. 6 to 14. The structure 600 provided by the steps described below further includes a support substrate 602.

In the step illustrated in FIG. 6, the semiconductor structure 10 is formed on a growth substrate 601. For example, the first semiconductor layer 11, the active layer 12, and the second semiconductor layer 13 are formed in this order on the growth substrate 601 by a metal organic chemical vapor deposition (MOCVD) method.

For example, an insulating substrate such as sapphire or spinel (MgAl₂O₄) with any of a C-plane, an R-plane, and an A-plane as a primary surface may be used as the growth substrate 601. A conductive substrate such as SiC (including 6H, 4H, and 3C), ZnS, ZnO, GaAs, or Si may be used as the growth substrate 601. In the present embodiment, a sapphire substrate having a C-plane as a primary surface is used as the growth substrate 601.

After the semiconductor structure 10 is formed on the growth substrate 601, the light-transmissive conductive film 90 is formed on the second semiconductor layer 13. For example, the light-transmissive conductive film 90 may be formed by a sputtering method.

After the light-transmissive conductive film 90 is formed, the first region 11B1 and the second region 11B2 are formed on the second surface 11B of the first semiconductor layer 11 by removing a part of the second semiconductor layer 13 and a part of the active layer 12 by, for example, dry etching using a resist as a mask.

After the first region 11B1 and the second region 11B2 are formed, the first electrode 61, the second electrode 62, the first reflective film 30, the second reflective film 80, the insulating film 50, the first conductive member 71, and the second conductive member 72 are formed. The first electrode 61, the second electrode 62, the first reflective film 30, the second reflective film 80, the insulating film 50, the first conductive member 71, and the second conductive member 72 may be formed by, for example, a sputtering method or a chemical vapor deposition (CVD) method.

The first electrode 61 is disposed on the second region 11B2 of the second surface 11B, and is in contact with the first semiconductor layer 11. The second electrode 62 is disposed on the light-transmissive conductive film 90 and is in contact with the light-transmissive conductive film 90. The first conductive member 71 connects the first electrode 61. The second conductive member 72 connects the second electrode 62.

The first reflective film 30 covers the second surface 11B, the active layer 12, the second semiconductor layer 13, the light-transmissive conductive film 90, the first electrode 61, and the second electrode 62. The second reflective film 80 is disposed on the first reflective film 30.

For example, after the first electrode 61, the second electrode 62, and the first reflective film 30 are formed, a part of the second semiconductor layer 13, a part of the active layer 12, and a part of the first semiconductor layer 11 are removed by, for example, dry etching using a resist as a mask to form a groove 15 in the semiconductor structure 10. The groove 15 does not reach the growth substrate 601. A portion of the first semiconductor layer 11 is left between the groove 15 and the first surface 11A of the first semiconductor layer 11 in contact with the growth substrate 601.

After the groove 15 is formed, the insulating film 50 is formed. The insulating film 50 covers the first reflective film 30 and the second reflective film 80. In addition, the insulating film 50 covers the surface of the semiconductor structure 10 that defines the groove 15.

The first conductive member 71 penetrates through the insulating film 50 and the first reflective film 30 to be connected to the first electrode 61, and is disposed on the insulating film 50. The second conductive member 72 penetrates through the insulating film 50 and the first reflective film 30 to be connected to the second electrode 62, and is disposed on the insulating film 50.

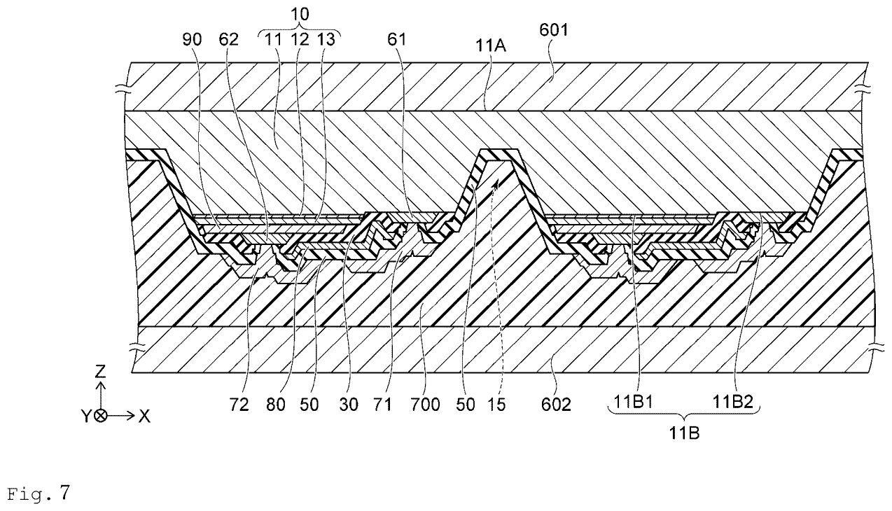

After the step illustrated in FIG. 6, as illustrated in FIG. 7, the second surface 11B side of the semiconductor structure 10 is bonded to the support substrate 602 via the support member 700. The support member 700 covers the first conductive member 71, the second conductive member 72, and the insulating film 50. In addition, the support member 700 is disposed in the groove 15 and covers the insulating film 50 in the groove 15. Note that, in FIG. 7, the vertical positional relationship between the growth substrate 601 and the semiconductor structure 10 is reversed from that illustrated in FIG. 6.

As the support substrate 602, for example, a substrate such as sapphire, spinel, SiC, ZnS, ZnO, GaAs, or Si may be used.

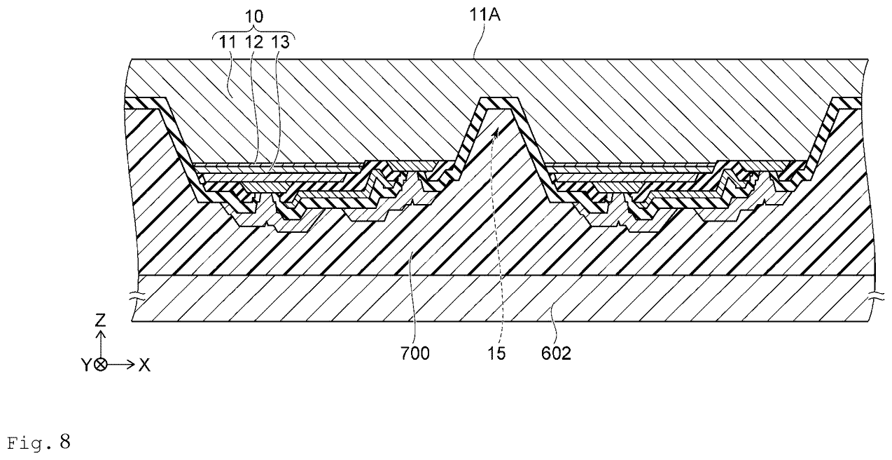

After the semiconductor structure 10 is bonded to the support substrate 602, the growth substrate 601 is removed to expose the first surface 11A of the first semiconductor layer 11 as illustrated in FIG. 8. The growth substrate 601 may be removed, for example, by a method such as laser lift-off, grinding, polishing, wet etching, or dry etching.

When the growth substrate 601 and the semiconductor structure 10 are separated by laser lift-off, as illustrated in FIG. 7, the laser lift-off may be performed in a state in which the first surface 11A of the semiconductor structure 10 in contact with the growth substrate 601 is not separated in an XY plane by the groove 15. In this case, the growth substrate 601 and the semiconductor structure 10 may be separated more easily in comparison with a case in which the first surface 11A in contact with the growth substrate 601 of the semiconductor structure 10 is separated in the XY plane. Note that the semiconductor structure 10 may be separated into a plurality of portions on the growth substrate 601 by forming the groove 15 to reach the growth substrate 601. In this case, a step of removing the first semiconductor layer 11 for separating the semiconductor structure 10, which will be described later, into a plurality of portions after removing the growth substrate 601 may be omitted.

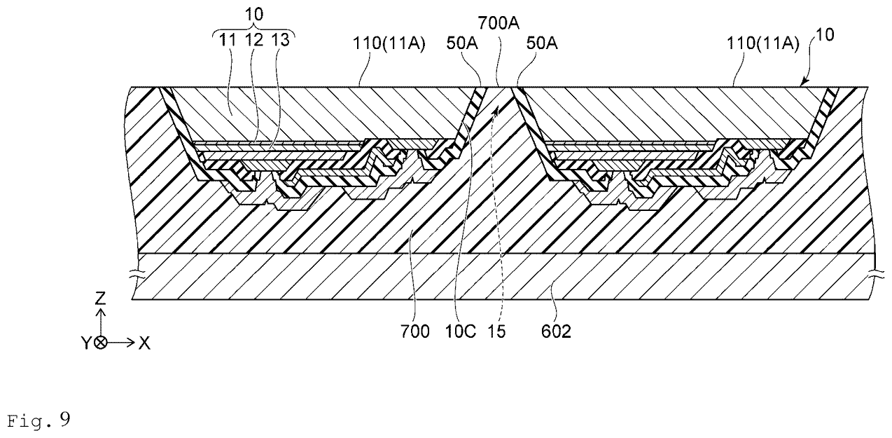

After the first surface 11A is exposed, for example, the first semiconductor layer 11 is removed from the first surface 11A side by a method such as polishing, wet etching, or dry etching. Examples of polishing include a chemical mechanical polishing (CMP) method, and examples of dry etching include a reactive ion etching (RIE) method. The first semiconductor layer 11 positioned above the groove 15 is removed. Accordingly, as illustrated in FIG. 9, the semiconductor structure 10 is separated into a plurality of portions. The first surface 11A in each of the individual semiconductor structures 10 separated from each other becomes the light-emitting surface 110 of the light-emitting element 100.

In addition, between adjacent semiconductor structures 10, an upper surface 700A of the support member 700 and an upper surface 50A of an end portion on a first surface 11A side in the insulating film 50 disposed on the lateral surface 10C of the semiconductor structure 10 are exposed from the semiconductor structure 10.

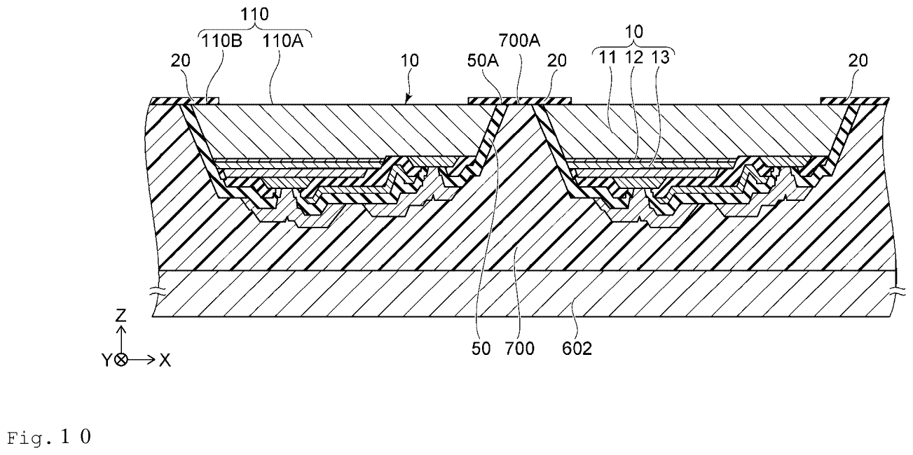

After the semiconductor structure 10 is separated into a plurality of portions, the first protective film 20 is formed as illustrated in FIG. 10. The first protective film 20 covers the outer peripheral region 110B of the light-emitting surface 110. In addition, the first protective film 20 covers the upper surface 50A of the insulating film 50 and the upper surface 700A of the support member 700 between adjacent semiconductor structures 10. The first protective film 20 may be formed, for example, by the CVD method.

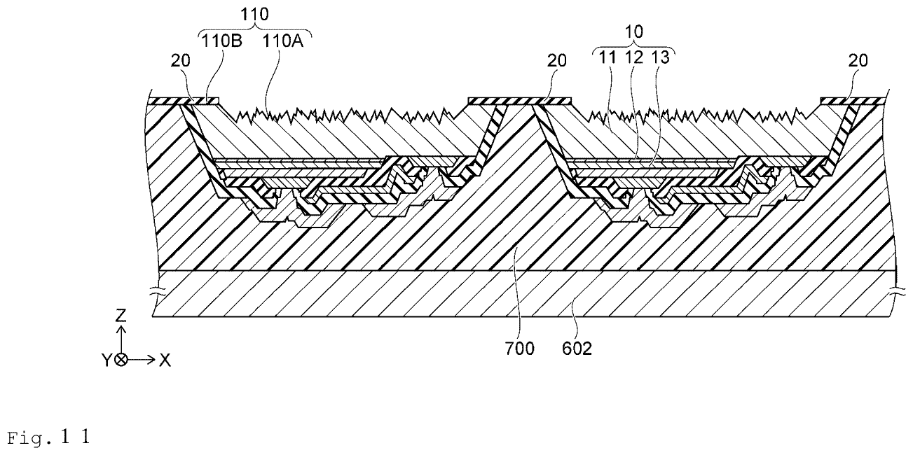

After the first protective film 20 is formed, as illustrated in FIG. 11, the inner region 110A of the light-emitting surface 110 exposed from the first protective film 20 is roughened. For example, the inner region 110A may be roughened by wet etching using an alkaline solution such as tetramethylammonium hydroxide (TMAH) or dry etching using a chlorine-containing gas. The roughened inner region 110A includes a plurality of protrusions. Because the outer peripheral region 110B of the light-emitting surface 110 covered with the first protective film 20 is not etched, roughening does not occur.

In a case in which the entire surface of the light-emitting surface 110 is roughened, chipping of the first semiconductor layer 11 tends to occur in the vicinity of the outer edge of the light-emitting surface 110. According to the present embodiment, by not roughening the outer peripheral region 110B of the light-emitting surface 110, the occurrence of chipping of the first semiconductor layer 11, which tends to occur in the vicinity of the outer edge of the light-emitting surface 110, can be reduced.

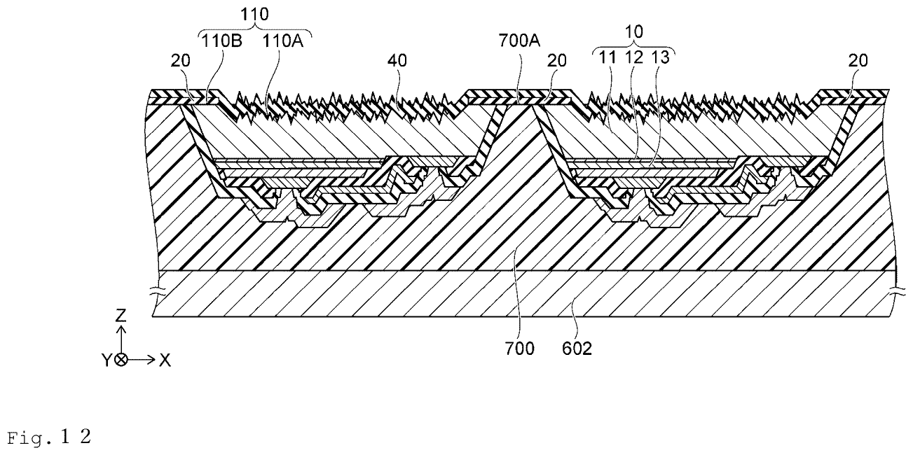

After the inner region 110A is roughened, as illustrated in FIG. 12, the second protective film 40 is continuously formed on the inner region 110A and the first protective film 20. The second protective film 40 may be formed, for example, by the CVD method. A plurality of protrusions are also formed on the upper surface of the second protective film 40 covering the inner region 110A including the plurality of protrusions.

After continuously forming the second protective film 40 on the inner region 110A and the first protective film 20, the first protective film 20 and the second protective film 40 positioned on the upper surface 700A of the support member 700 are removed. As a result, as illustrated in FIG. 14, the upper surface 700A of the support member 700 positioned between the plurality of light-emitting elements 100 is exposed from the first protective film 20 and the second protective film 40. For example, the first protective film 20 and the second protective film 40 positioned on the upper surface 700A of the support member 700 may be removed by dry etching using a resist as a mask.

The structure 600 may be provided by the steps described above. In the structure 600, the first protective film 20 and the second protective film 40 are formed on the light-emitting surfaces 110 of the plurality of light-emitting elements 100 such that the support member 700 positioned between the plurality of light-emitting elements 100 is exposed. The first protective film 20 and the second protective film 40 are separated for each light-emitting element 100. The structure 600 may be provided by purchase.

### Step of Disposing Mask Member on Structure

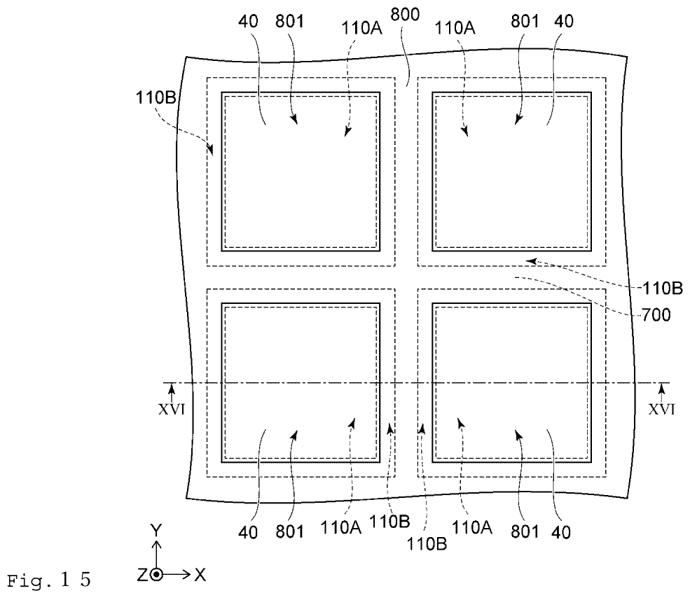

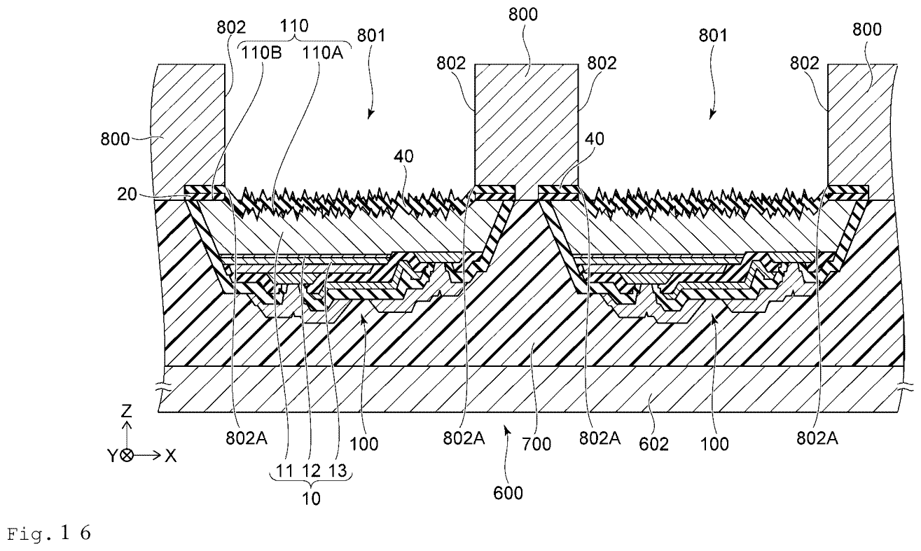

The method for manufacturing the light-emitting device according to the first embodiment includes a step of disposing a mask member 800 on the structure 600 as illustrated in FIGS. 15 and 16.

The mask member 800 covers the upper surface 700A of the support member 700 between the plurality of light-emitting elements 100. According to the present embodiment, the mask member 800 covers the second protective film 40 positioned above the outer peripheral region 110B of the light-emitting surface 110.

The mask member 800 has a plurality of openings 801 defined above the respective light-emitting surfaces 110 of the plurality of light-emitting elements 100. One opening 801 is positioned above one light-emitting surface 110. According to the present embodiment, the opening 801 is positioned above the inner region 110A of the light-emitting surface 110. In the opening 801, the second protective film 40 on the inner region 110A is exposed.

For example, a state in which the opening 801 is defined in the resist may be referred to as a mask member 800. The step of disposing a mask member 800 includes a step of continuously forming a resist on the upper surface of the second protective film 40, which is the upper surface of the light-emitting elements 100, and on the upper surface 700A of the support member 700 between the plurality of light-emitting elements 100. Further, the step of disposing a mask member 800 includes a step of forming an opening 801 by removing a resist above the inner region 110A through exposure and development after forming the resist.

According to the present embodiment, in the step of disposing a mask member 800, a lower end 802A of an inner lateral surface 802 of the mask member 800 defining the opening 801 is positioned on the outer peripheral region 110B of the light-emitting surface 110. In other words, the lower end 802A of the inner lateral surface 802 of the mask member 800 is not positioned on the inner region 110A of the light-emitting surface 110.

### Step of Disposing Wavelength Conversion Members in Plurality of Openings

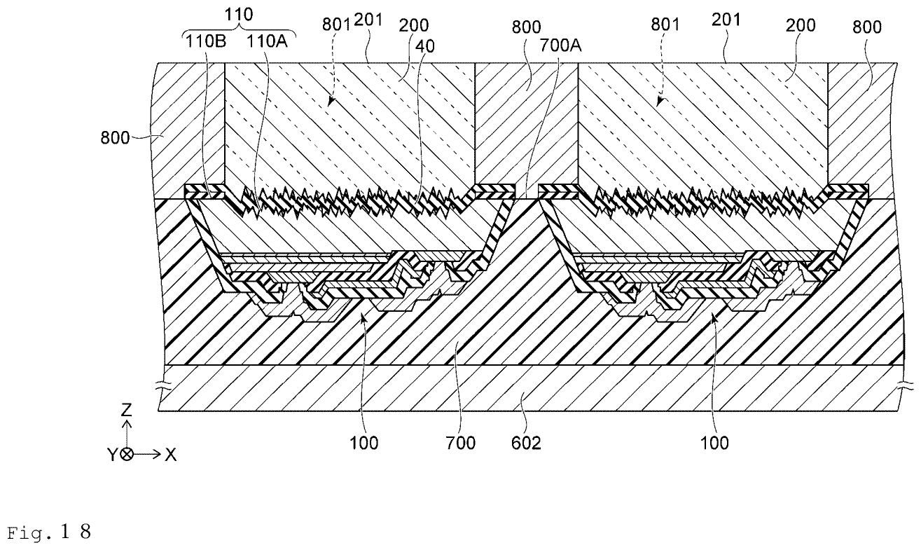

The method for manufacturing the light-emitting device according to the first embodiment includes, as illustrated in FIG. 18, a step of disposing wavelength conversion members 200 in the plurality of openings 801.

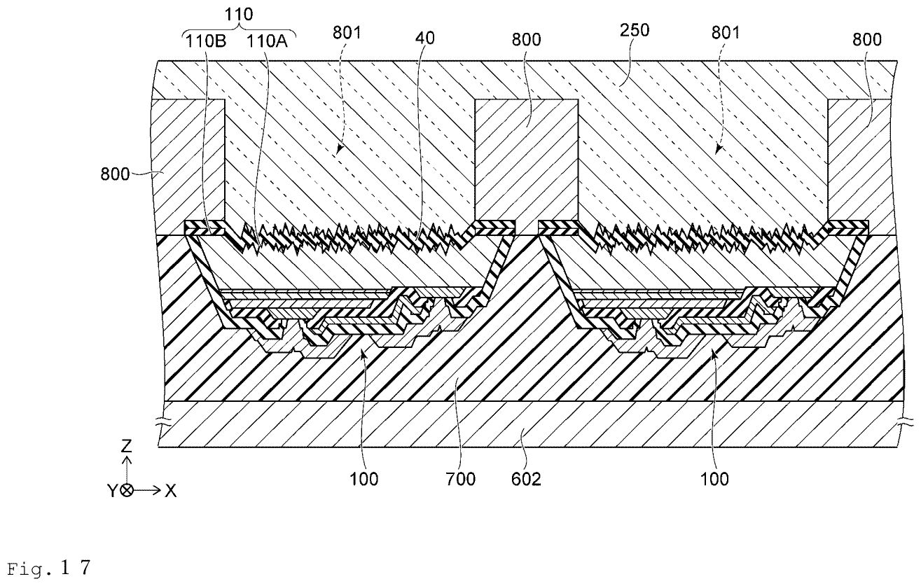

The step of disposing wavelength conversion members 200 includes, for example, as illustrated in FIG. 17, a step of disposing a wavelength conversion material 250 in the plurality of openings 801 and on the upper surface of the mask member 800. The wavelength conversion material 250 may be disposed in the plurality of openings 801 and on the upper surface of the mask member 800 by, for example, a dispenser.

Furthermore, the step of disposing wavelength conversion members 200 includes a step of removing a portion of the wavelength conversion material 250 and a portion of the mask member 800 after curing the wavelength conversion material 250. The wavelength conversion material 250 may be cured, for example, by heating. The portion of the wavelength conversion material 250 and the portion of the mask member 800 may be removed, for example, by grinding. Thus, as illustrated in FIG. 18, in each of the plurality of openings 801, a wavelength conversion member 200 separated from the wavelength conversion members 200 in other openings 801 may be disposed.

By disposing the wavelength conversion material 250 in the plurality of openings 801 and on the upper surface of the mask member 800 and then removing the portion of the wavelength conversion material 250 and the portion of the mask member 800 by grinding, variations in height in the first direction Z of the upper surface 201 of the plurality of wavelength conversion members 200 separated for each of the plurality of light-emitting elements 100 can be reduced. Accordingly, variations in thickness of the plurality of wavelength conversion members 200 and variations in chromaticity of the plurality of wavelength conversion members 200 can be reduced.

### Step of Removing Mask Member and Support Member Between Plurality of Light-Emitting Elements

The method for manufacturing the light-emitting device according to the first embodiment includes a step of removing the mask member 800 and the support member 700 between the plurality of light-emitting elements 100 after disposing the wavelength conversion members 200.

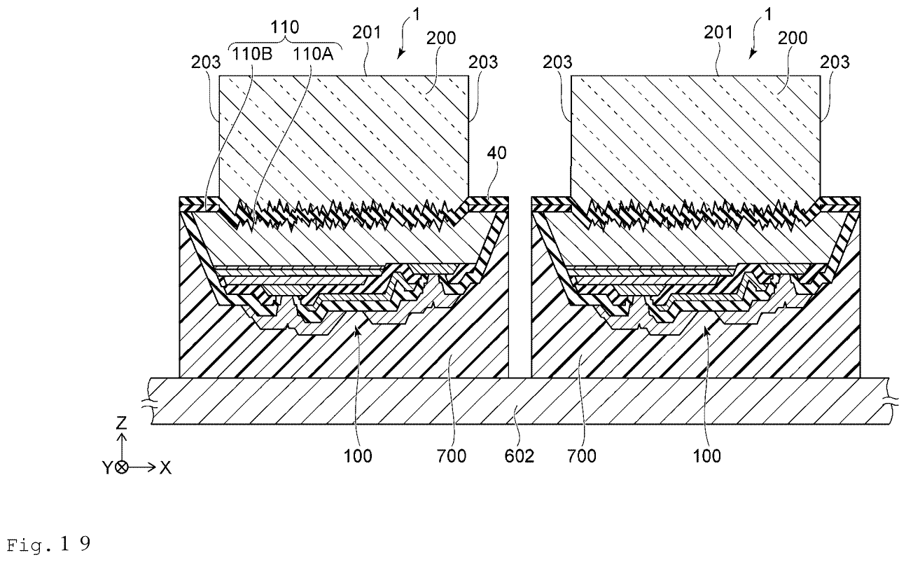

Thus, the plurality of light-emitting elements 100 collectively supported by the support member 700 are separated as illustrated in FIG. 19. The plurality of light-emitting devices 1 each including the light-emitting element 100 and the wavelength conversion member 200 on the light-emitting element 100 are supported on the support substrate 602 via the support member 700 remaining between the light-emitting element 100 and the support substrate 602 in a state of being separated from each other.

In the step of removing the mask member 800 and the support member 700 between the plurality of light-emitting elements 100, the mask member 800 and the support member 700 may be removed by dry etching with the same gas. Accordingly, the step may be simplified as compared with the case where the removal of the mask member 800 and the removal of the support member 700 are performed by separate etching. For example, the mask member 800 and the support member 700 may be continuously removed by dry etching using a gas containing oxygen. The mask member 800 is first removed to expose the upper surface 700A of the support member 700 between the plurality of light-emitting elements 100. The support member 700 between the plurality of light-emitting elements 100 is removed by etching proceeding from the upper surface 700A.

Alternatively, the mask member 800 may be removed by wet etching, and thereafter, the support member 700 may be removed by dry etching.

According to the present embodiment, a plurality of wavelength conversion members 200 separated from each other may be formed for corresponding one of the light-emitting elements 100. Accordingly, when light emission control is individually performed for the plurality of light-emitting elements 100, light emitted from the light-emitting element 100 that is intentionally lit is less likely to enter into the wavelength conversion member 200 on the light-emitting element 100 that is intentionally unlit.

In the step of disposing a mask member 800, when the mask member 800 is disposed between the plurality of protrusions in the upper surface of the second protective film 40 on the inner region 110A of the light-emitting surface 110, the mask member 800 disposed between the plurality of protrusions is likely to remain without being removed in the step of removing the mask member 800. The mask member 800 remaining between the plurality of protrusions may reduce light extraction efficiency.

According to the present embodiment, in the step of disposing a mask member 800 illustrated in FIG. 16, the lower end 802A of the inner lateral surface 802 of the mask member 800 that defines the opening 801 is positioned on the outer peripheral region 110B of the light-emitting surface 110, so that the mask member 800 is not disposed between a plurality of protrusions on the upper surface of the second protective film 40 on the inner region 110A of the light-emitting surface 110.

The first protective film 20 and the second protective film 40 on the upper surface 700A of the support member 700 between the plurality of light-emitting elements 100 may be removed after the wavelength conversion member 200 is formed. For example, after removing the mask member 800, the second protective film 40 and the first protective film 20 on the upper surface 700A of the support member 700 may be sequentially removed by dry etching using a resist as a mask. However, in this case, the resist formed to remove the second protective film 40 and the first protective film 20 needs to cover a large step between the thick wavelength conversion member 200 having a thickness of, for example, 10 μm or more and the second protective film 40 on the outer peripheral region 110B of the light-emitting surface 110, which is highly difficult.

In a case in which the second protective film 40 and the first protective film 20 on the upper surface 700A of the support member 700 are removed before the wavelength conversion member 200 is formed as in the present embodiment described above, a resist for removing the second protective film 40 and the first protective film 20 may be easily formed.

### Method for Manufacturing Light-Emitting Device According to Second Embodiment

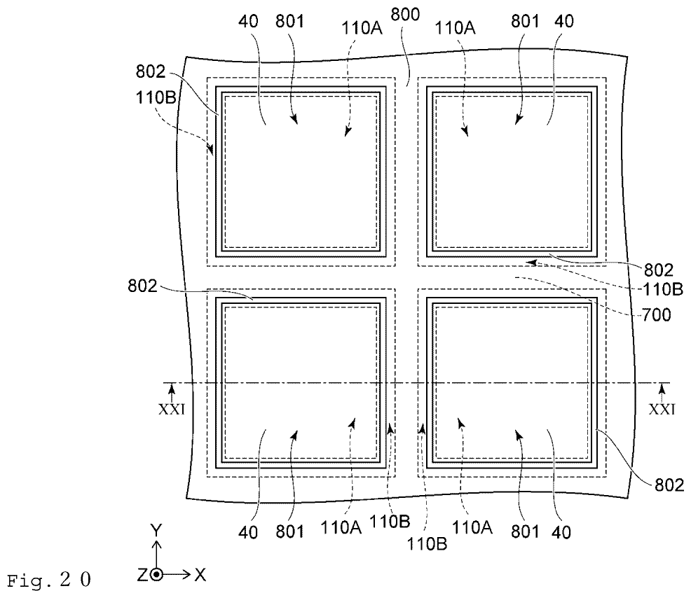

A method for manufacturing the light-emitting device according to the second embodiment will be described with reference to FIGS. 20 to 22.

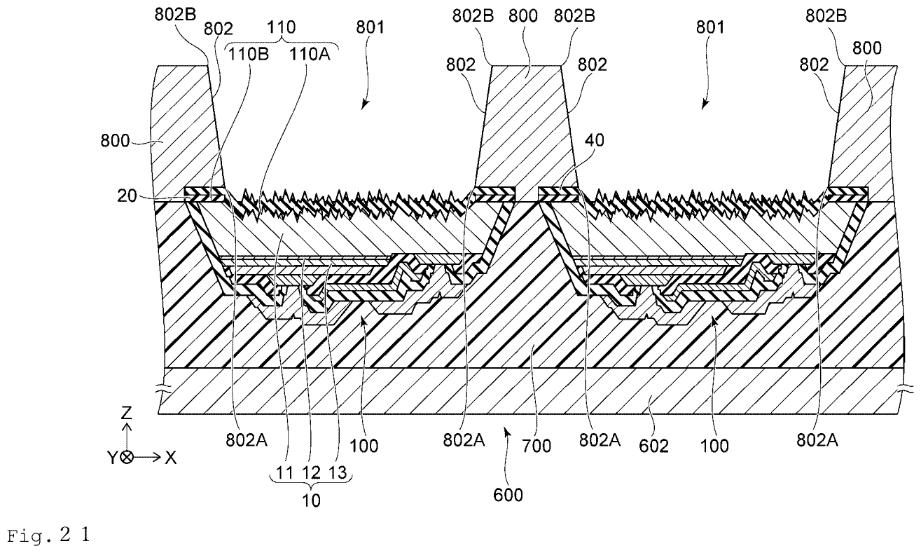

According to the method for manufacturing the light-emitting device according to the second embodiment, in the step of disposing a mask member 800, as illustrated in FIGS. 20 and 21, an upper end 802B of the inner lateral surface 802 of the mask member 800 is positioned outward of the lower end 802A of the inner lateral surface 802 and is positioned to overlap the outer peripheral region 110B of the light-emitting surface 110 in a plan view. In a cross-sectional view, the inner lateral surface 802 is inclined such that a width of the opening 801 increases from the light-emitting element 100 toward the upper surface of the mask member 800.

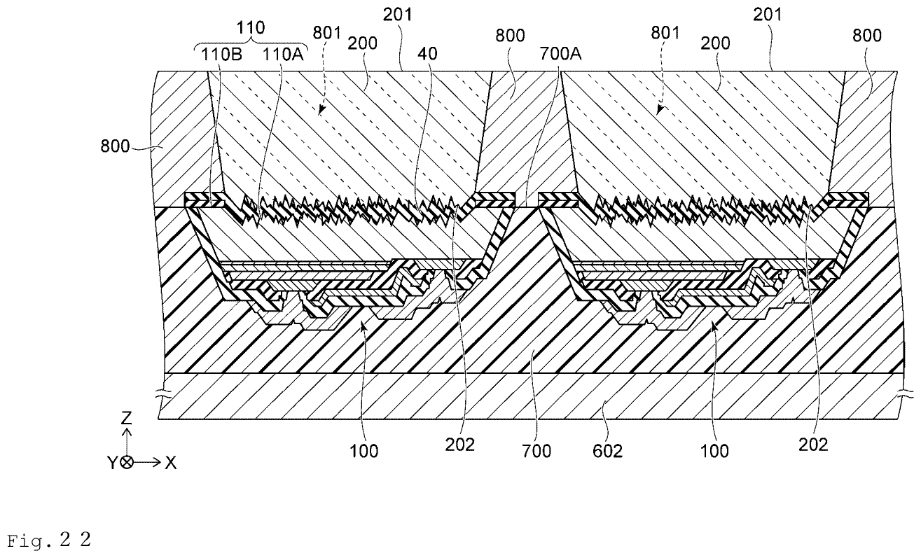

In the wavelength conversion member 200 disposed in the opening 801 of the mask member 800 by the method for manufacturing the light-emitting device according to the second embodiment, as illustrated in FIG. 22, the width in a cross-sectional view increases from the lower surface 202 toward the upper surface 201. According to the method for manufacturing the light-emitting device of the second embodiment, the area of the upper surface 201 of the wavelength conversion member 200 can be increased while the lower surface 202 of the wavelength conversion member 200 is not positioned on the outer peripheral region 110B of the light-emitting surface 110. Accordingly, a light-emitting area of the light-emitting device 1 can be increased while reducing variations in chromaticity.

### Method for Manufacturing Light-Emitting Module

A method for manufacturing the light-emitting module according to the embodiment can include steps to be described below.

The support member 700 is irradiated with laser light from a support substrate 602 side that supports the plurality of light-emitting devices 1 illustrated in FIG. 19. Thus, at least a portion of the support member 700 between the support substrate 602 and the light-emitting device 1 is removed, the light-emitting device 1 is separated from the support substrate 602, and the upper surface 201 of the wavelength conversion member 200 in the light-emitting device 1 is bonded to, for example, another support substrate having adhesiveness. Alternatively, after the upper surface 201 of the wavelength conversion member 200 is bonded to the other support substrate, the support member 700 may be irradiated with laser light to separate the light-emitting device 1 from the support substrate 602.

After separating the light-emitting device 1 from the support substrate 602, the support member 700 remaining on a surface side of a light-emitting element 100 positioned on the opposite side of the light-emitting surface 110 is removed, as necessary. As a result, the first conductive member 71 and the second conductive member 72 are exposed. The support member 700 remaining on the light-emitting element 100 may be removed by, for example, dry etching.

The plurality of light-emitting devices 1 are disposed on the wiring substrate 400 illustrated in FIG. 5 from the other support substrate. The first conductive member 71 and the second conductive member 72 of each of the plurality of light-emitting devices 1 are bonded to the wiring portion 402 of the wiring substrate 400 via the connection member 410.

After the plurality of light-emitting devices 1 are disposed on the wiring substrate 400, the light-reflective member 500 is disposed between adjacent light-emitting elements 100 and between adjacent wavelength conversion members 200. For example, after a frame member is disposed on the wiring substrate 400 so as to surround an arrangement region of the plurality of light-emitting devices 1, the light-reflective member 500 in a liquid state is supplied to the inside of the frame member and cured.

As a comparative example, a method for manufacturing a light-emitting module including a step of disposing a plurality of light-emitting elements on a wiring substrate using a chip mounter or the like, a step of disposing a first light-reflective member between the plurality of light-emitting elements on the wiring substrate, a step of disposing a wavelength conversion member on a light-emitting surface of each of the plurality of light-emitting elements using a mask member having a plurality of openings positioned above the light-emitting surface of each of the plurality of light-emitting elements after the step of disposing a first light-reflective member, and a step of disposing a second light-reflective member between the plurality of wavelength conversion members by removing the mask member may be considered. In this case, in the step of disposing a plurality of light-emitting elements on the wiring substrate, the pitch between the plurality of light-emitting elements is likely to vary, and the position of the opening of the mask member and the position of the light-emitting element are likely to deviate from each other. In other words, the position of the wavelength conversion member disposed in the opening of the mask member and the position of the light-emitting element are likely to deviate from each other.

According to the present embodiment, as illustrated in FIG. 18 and the like, the wavelength conversion member 200 is formed on the light-emitting surfaces 110 of the plurality of light-emitting elements 100 on the support substrate 602 using the mask member 800. In the plurality of light-emitting elements 100 on the support substrate 602, the pitch of the portions to be the light-emitting elements 100 partitioned by the grooves 15 illustrated in FIG. 6 is maintained. Because each step performed on the growth substrate 601 may be performed with high accuracy, a pitch of portions to become the light-emitting element 100 partitioned by the groove 15 has little variation. Therefore, according to the present embodiment, the wavelength conversion member 200 may be disposed on the light-emitting surface 110 of the light-emitting element 100 with high accuracy.

Embodiments of the present disclosure can include the method for manufacturing the light-emitting device, the light-emitting device, and the light-emitting module described below.

Embodiments of the present disclosure have been described above with reference to specific examples. However, the present disclosure is not limited to these specific examples. All aspects that can be practiced by a person skilled in the art modifying the design as appropriate based on the above-described embodiments of the present disclosure are also included in the scope of the present disclosure, as long as they encompass the spirit of the present disclosure. In addition, in the scope of the concepts of the present disclosure, a person skilled in the art can conceive of various variations and alternative embodiments, and those variations and alternative embodiments also fall within the scope of the present disclosure.

### REFERENCE CHARACTER LIST

1 to 2: Light-emitting device, 10: Semiconductor structure, 11: First semiconductor layer, 12: Active layer, 13: Second semiconductor layer, 20: First protective film, 30: First reflective film, 40: Second protective film, 50: Insulating film, 61: First electrode, 62: Second electrode, 71: First conductive member, 72: Second conductive member, 80: Second reflective film, 90: Light-transmissive conductive film, 100: Light-emitting element, 110: Light-emitting surface, 110A: Inner region, 110A1: Outer edge of inner region, 110B: Outer peripheral region, 110B1: Outer edge of outer peripheral region, 200: Wavelength conversion member, 201: Upper surface of wavelength conversion member, 202: Lower surface of wavelength conversion member, 203: Lateral surface of wavelength conversion member, 250: Wavelength conversion material, 300: Light-emitting module, 400: Wiring substrate, 401: Insulating base body, 402: Wiring portion, 410: Connection member, 500: Light-reflective member, 600: Structure, 601: Growth substrate, 602: Support substrate, 700: Support member, 800: Mask member

What is claimed is:

1. A method for manufacturing a light-emitting device, the method comprising:
providing a structure comprising:
a plurality of light-emitting elements each having a light-emitting surface, and
a support member disposed at least between the plurality of light-emitting elements and supporting the plurality of light-emitting elements;
disposing, on the structure, a mask member covering the support member between the plurality of light-emitting elements, the mask member defining a plurality of openings each positioned above a corresponding one of the light-emitting surfaces of the plurality of light-emitting elements;
disposing a plurality of wavelength conversion members in the plurality of openings; and
after disposing the plurality of wavelength conversion members, removing the mask member and the support member between the plurality of light-emitting elements.

2. The method for manufacturing a light-emitting device according to claim 1, wherein:
the providing of the structure comprises forming a protective film on the light-emitting surfaces of the plurality of light-emitting elements, and
the support member is partially exposed from the protective film.

3. The method for manufacturing a light-emitting device according to claim 1, wherein:
each of the light-emitting surfaces of the plurality of light-emitting elements includes an outer peripheral region and an inner region surrounded by the outer peripheral region in a plan view,
a surface roughness of the inner region is greater than a surface roughness of the outer peripheral region, and
in the disposing of the mask member, a lower end of an inner lateral surface of the mask member defining the plurality of openings is positioned on the outer peripheral region.

4. The method for manufacturing a light-emitting device according to claim 2, wherein:
each of the light-emitting surfaces of the plurality of light-emitting elements includes an outer peripheral region and an inner region surrounded by the outer peripheral region in a plan view,
a surface roughness of the inner region is greater than a surface roughness of the outer peripheral region, and
in the disposing of the mask member, a lower end of an inner lateral surface of the mask member defining the plurality of openings is positioned on the outer peripheral region.

5. The method for manufacturing a light-emitting device according to claim 3, wherein:
in the plan view, an upper end of the inner lateral surface is positioned outward of the lower end of the inner lateral surface and positioned to overlap the outer peripheral region.

6. The method for manufacturing a light-emitting device according to claim 4, wherein:
in the plan view, an upper end of the inner lateral surface is positioned outward of the lower end of the inner lateral surface and positioned to overlap the outer peripheral region.

7. The method for manufacturing a light-emitting device according to claim 1, wherein:
the disposing of the wavelength conversion members comprises:
disposing a wavelength conversion material in the plurality of openings and on an upper surface of the mask member, and
removing a portion of the wavelength conversion material and a portion of the mask member by grinding to provide, in each of the plurality of openings, the wavelength conversion member separated from the wavelength conversion members in other openings.

8. The method for manufacturing a light-emitting device according to claim 2, wherein:
the disposing of the wavelength conversion members comprises:
disposing a wavelength conversion material in the plurality of openings and on an upper surface of the mask member, and
removing a portion of the wavelength conversion material and a portion of the mask member by grinding to provide, in each of the plurality of openings, the wavelength conversion member separated from the wavelength conversion members in other openings.

9. The method for manufacturing a light-emitting device according to claim 3, wherein:
the disposing of the wavelength conversion members comprises:
disposing a wavelength conversion material in the plurality of openings and on an upper surface of the mask member, and
removing a portion of the wavelength conversion material and a portion of the mask member by grinding to provide, in each of the plurality of openings, the wavelength conversion member separated from the wavelength conversion members in other openings.

10. The method for manufacturing a light-emitting device according to claim 1, wherein:
in the removing of the mask member and the support member, the removing is performed by dry etching using a same gas for the mask member and the support member.

11. The method for manufacturing a light-emitting device according to claim 3, wherein:
in the removing of the mask member and the support member, the removing is performed by dry etching using a same gas for the mask member and the support member.

12. A light-emitting device comprising:
a light-emitting element having a light-emitting surface, the light-emitting surface including an outer peripheral region and an inner region surrounded by the outer peripheral region in a plan view, a surface roughness of the inner region being greater than a surface roughness of the outer peripheral region; and
a wavelength conversion member disposed on the light-emitting surface, wherein:
a lower surface of the wavelength conversion member is positioned on the inner region and is not positioned on the outer peripheral region.

13. The light-emitting device according to claim 11, wherein:
the wavelength conversion member further has an upper surface positioned on a side opposite the lower surface, and
in a plan view, an outer edge of the upper surface is positioned outward of an outer edge of the lower surface and overlaps the outer peripheral region of the light-emitting surface of the light-emitting element.

14. A light-emitting module comprising:
a wiring substrate;
a plurality of the light-emitting devices according to claim 11, each disposed on the wiring substrate, with a surface positioned on an opposite side of the light-emitting surface of the light-emitting element facing the wiring substrate; and
a light-reflective member disposed between the plurality of light-emitting elements of the plurality of the light-emitting devices and between the plurality of wavelength conversion members of the plurality of the light-emitting devices.

15. A light-emitting module comprising:
a wiring substrate;
a plurality of the light-emitting devices according to claim 12, each disposed on the wiring substrate, with a surface positioned on an opposite side of the light-emitting surface of the light-emitting element facing the wiring substrate; and
a light-reflective member disposed between the plurality of light-emitting elements of the plurality of the light-emitting devices and between the plurality of wavelength conversion members of the plurality of the light-emitting devices.
